(19) United States
(12) Patent Application Publication
(10) Pub. No.: US 2010/0033287 A1
(43) Pub. Date: Feb. 11, 2010

(54) INTEGRATED PASSIVE DEVICE AND IPD TRANSFORMER

(75) Inventors: Ki Joong Kim, Iksan (KR); Young Sik Kang, Daejeon (KR); Su Bong Jang, Anyang (KR); Youn Suk Kim, Yongin (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/332,150

(22) Filed: Dec. 10, 2008

(30) Foreign Application Priority Data
Aug. 8, 2008 (KR) 10-2008-0077970

(51) Int. Cl. H01F 5/00; H05K 1/00; H05K 1/03; H05K 1/09

(52) U.S. Cl. 336/200; 174/250; 174/255; 174/256; 174/257

(57) ABSTRACT

Provided are an integrated passive device (IPD) and an IPD transformer. The integrated passive device includes a dielectric laminated substrate, a first conductive layer, a buffer layer, and a second conductive layer. The first conductive layer is formed in the dielectric laminated substrate. The buffer layer is formed on one region of the first conductive layer in the dielectric laminated substrate. The second conductive layer is formed on the buffer layer such that a portion of the second conductive layer is exposed to the outside of the dielectric laminated substrate.

### CROSS-REFERENCE TO RELATED APPLICATIONS

This application claims the priority of Korean Patent Application No. 2008-0077970 filed on Aug. 8, 2008, in the Korean Intellectual Property Office, the disclosure of which is incorporated herein by reference.

### BACKGROUND OF THE INVENTION

1. Field of the Invention

The present invention relates to an integrated passive device (IPD) and an IPD transformer, and more particularly, to an integrated passive device (IPD) and an IPD transformer, which has a structure capable of minimizing a direct current (DC) resistance in a power-on mode.

2. Description of the Related Art

Recently, there is an increasing demand for the high integration and the high operation speed of a semiconductor device. However, in the case of a semiconductor integrated circuit with a single-layer interconnection, a decrease in the occupation area due to high integration reduces the width of a metal interconnection and thus increases an electrical resistance, thereby increasing the power consumption. Thus, a multi-layer interconnection has been proposed to increase the operation speed while maximally suppressing an increase in the electrical resistance of an interconnection.

A power amplifier (PA) is used in a transmitting side of a mobile communication terminal, such as a portable phone, in order to amplify the power of a transmission signal. Such a power amplifier must amplify a transmission signal to a suitable power. Examples of methods for amplifying the output power of a power amplifier are a closed loop method and an open loop method. In the closed loop method, a transformer is used to detect some of output signals at an output terminal of a power amplifier, a Schottky diode is used to convert the detected signal into a DC current, and a comparator is used to compare the same with a reference voltage. In the open loop method, a voltage or a current applied to a power amplifier is sensed to control the power of the power amplifier.

The closed loop method is a conventionally used method. The closed loop method is advantageous in that it can provide a fine power control. However, the closed loop method is disadvantageous in that it degrades the efficiency of an amplifier due to the complexity of circuit implementation and a loss caused by a coupler. The open loop method is a widely used method. The open loop method is advantageous in that it can provide a simple circuit implementation. However, the open loop method is disadvantageous in that it cannot provide a fine power control.

Recently, the components used in the closed loop method are implemented using integrated circuits (ICs), and thus the circuit implementation becomes simple. Also, the performance of a control chip is enhanced and a coupling value of a directional coupler is greatly reduced, so that a loss caused by the directional coupler is greatly reduced. Particularly, the closed loop method capable of providing a fine power control is used in a GSM communication scheme in which a ramping profile is important.

Researches are being continuously conducted to effectively implement a transformer for controlling the output of the power amplifier. However, in implementation of the transformer, a harmonic component is generated in the output signal and also the size of coupling varies according the locations of a power supply pad.

### SUMMARY OF THE INVENTION

An aspect of the present invention provides an integrated passive device (IPD) and an IPD transformer, which has a structure capable of minimizing a direct current (DC) resistance when power is applied from the outside.

According to an aspect of the present invention, there is provided an integrated passive device including: a dielectric laminated substrate; a first conductive layer formed in the dielectric laminated substrate; a buffer layer formed on one region of the first conductive layer in the dielectric laminated substrate; and a second conductive layer formed on the buffer layer such that a portion of the second conductive layer is exposed to the outside of the dielectric laminated substrate.

The dielectric laminated substrate may include benzocyclobutene (BCB).

The first conductive layer may be an inductor pattern with a predetermined electrical length.

The buffer layer may include a titanium (Ti)-based metal.

The second conductive layer may include aurum (Au) and nickel (Ni).

The dielectric laminated substrate may include: a first dielectric layer with a first permittivity; and a second dielectric layer with a second permittivity, wherein the first conductive layer, the buffer layer, and the second conductive layer may be formed on the second dielectric layer. Herein, the second dielectric layer may include benzocyclobutene (BCB).

According to another aspect of the present invention, there is provided an integrated passive device (IPD) transformer including: a dielectric laminated substrate; at least one input conductive line formed on the dielectric laminated substrate, both ends of the input conductive line being provided respectively as input terminals of a ‘+’ signal and a ‘−’ signal; an output conductive line formed to be adjacent to the input conductive line such that the output conductive line generates an electromagnetic coupling with the input conductive line, one end of the output conductive line being connected to an output terminal, the other end of the output conductive line being connected to a ground terminal; a buffer layer formed in one region of the input conductive line; and a power supply pad formed on the buffer layer such that a portion of the power supply pad is exposed to the outside of the dielectric laminated substrate, wherein a portion of the input conductive line is formed in one layer of the dielectric laminated substrate and the other portion of the input conductive line is formed in the other layer different from the one layer of the dielectric laminated substrate and is connected through a via hole; and a portion of the output conductive line is formed in one layer of the dielectric laminated substrate and the other portion of the output conductive line is formed in the other layer different from the one layer of the dielectric laminated substrate and is connected through a via hole, such that the output conductive line is not directly connected to the input conductive line.

The dielectric laminated substrate may include benzocyclobutene (BCB).

The buffer layer may include a titanium (Ti)-based metal.

The power supply pad may include aurum (Au) and nickel (Ni)

The dielectric laminated substrate may include: a first dielectric layer with a first permittivity; and a second dielectric layer with a second permittivity, wherein the input conductive line, the buffer layer, and the power supply pad are formed on the second dielectric layer. Herein, the second dielectric layer may include benzocyclobutene (BCB).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of an integrated passive device (IPD) according to an exemplary embodiment of the present invention;

FIG. 2 is a plan view of an IPD transformer according to another exemplary embodiment of the present invention; and

FIG. 3 is a cross-sectional view taken along a line AA′ of FIG. 2.

### DETAILED DESCRIPTION OF THE PREFERRED EMBODIMENT

Exemplary embodiments of the present invention will now be described in detail with reference to the accompanying drawings.

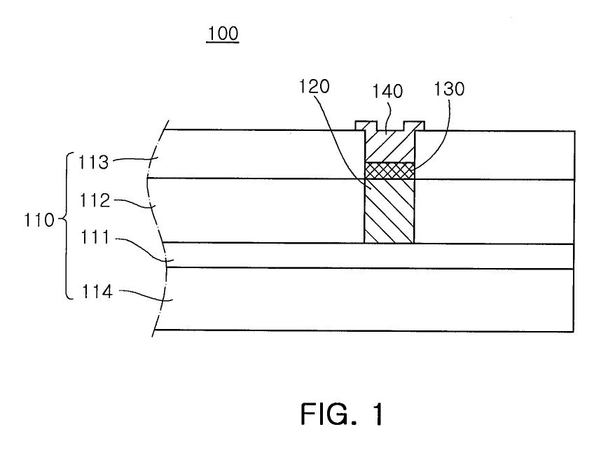

FIG. 1 is a cross-sectional view of an integrated passive device (IPD) according to an exemplary embodiment of the present invention.

Referring to FIG. 1, an integrated passive device 100 according to the present embodiment may include a laminated substrate 110, a first conductive layer 120, a buffer layer 130, and a second conductive layer 140.

The laminated substrate 110 may include a plurality of dielectric sheets 111, 112 and 113 that are laminated therein. The dielectric sheets 111, 112 and 113 may contain benzocyclobutene (BCB). The benzocyclobutene is a dielectric material with a permittivity of about 2.

The laminated substrate 110 may further include a second dielectric layer 114 that has a different permittivity than the dielectric sheets 111, 112 and 113. The second dielectric layer 114 may be a ceramic laminated body. The laminated substrate 110 may be a semiconductor substrate.

In the present embodiment, the BCB layers 111, 112 and 113 may be formed on the ceramic laminated layer 114 and the first conductive layer 120 may be formed in the BCB layers 111, 112 and 113.

The first conductive layer 120 may be a conductor pattern that is formed in the laminated substrate 110. In the present embodiment, although only the section of a partial region of the laminated substrate 110 is illustrated in FIG. 1, the first conductive layer 120 may be an inductor pattern with a predetermined electrical length.

The first conductive layer 120 may be implemented in such a way that one portion is formed in one layer of the laminated substrate 110, the other portion is formed in the other layer, and they are connected to each other by a via hole.

In addition to the first conductive layer 120, a conductive pattern forming a capacitor may be formed in the laminated substrate 110.

The buffer layer 130 may be formed on one region of the first conductive layer 120. Te buffer layer 130 may contain a titanium (Ti)-based metal. The buffer layer 130 may be formed between the first conductive layer 120 and the second conductive layer 140 to serve as a barrier.

The second conductive layer 140 may be formed on the buffer layer 130. A portion of the second conductive layer 140 may be exposed on the surface of the laminated substrate 110. The exposed portion of the second conductive layer 140 may be used for connection with an external circuit. The exposed portion of the second conductive layer 140 may be provided as a pad for wire bonding.

The second conductive layer 140 may be formed by plating nickel (Ni) and/or aurum (Au) on the buffer layer 130.

In the present embodiment, the first conductive layer 120 may be formed in the benzocyclobutene (BCB) laminated substrate 110, and the buffer layer 130 may be formed in order to form the second conductive layer 140 on the first conductive layer 120.

The first conductive layer 120 may be formed of cuprum (Cu). The second conductive layer 140 may be a Ni/Au plating layer. If the second conductive layer 140 is formed directly on the first conductive layer 120 formed of cuprum (Cu), the cuprum particles of the first conductive layer 120 may be transferred to the second conductive layer 140. In order to prevent this transfer phenomenon, the buffer layer 130 may be formed between the first conductive layer 120 and the second conductive layer 140.

If only a seed layer (not illustrated) is formed on the first conductive layer 120 formed of cuprum (Cu) and then the second conductive layer 140 is formed thereon, the benzocyclobutene (BCB) may infiltrate between the first conductive layer 120 and the second conductive layer 140 because of the characteristics of the BCB layer. Therefore, the first conductive layer 120 and the second conductive layer 140 may come off from each other, thus leading to a contact failure therebetween.

In the present embodiment, the buffer layer 130 is formed between the first conductive layer 120 and the second conductive layer 140, thereby making it possible to prevent the benzocyclobutene (BCB) from infiltrating between the first conductive layer 120 and the second conductive layer 140.

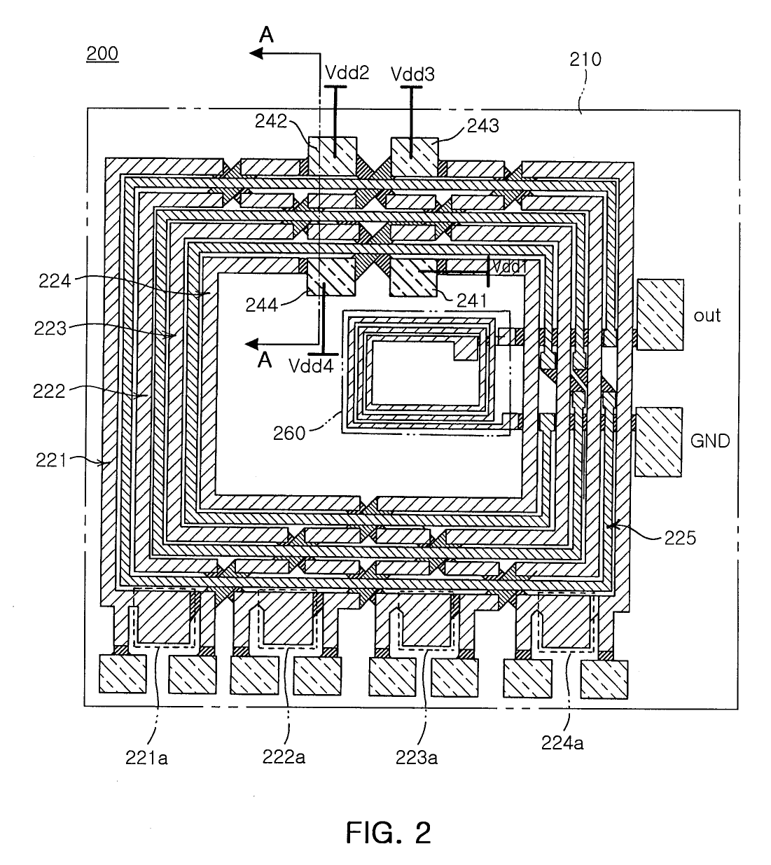

FIG. 2 is a plan view of an IPD transformer according to another exemplary embodiment of the present invention.

Referring to FIG. 2, an IPD transformer 200 according to the present embodiment may include a laminated substrate 210; a plurality of input conductive lines 221, 222, 223 and 224 formed in the laminated substrate 210; an output conductive line 225; and a plurality of power supply pads 214, 242, 243 and 244 constituting the portions of the input conductive lines 221, 222, 223 and 224.

The laminated substrate 210 may be formed to have a plurality of layers.

In the present embodiment, the input conductive line and the output conductive line may be respectively formed on the top of the laminated substrate and the other layer different from the top of the laminated substrate and may be connected through a via hole so that they are not directly connected to each other. The laminated substrate 210 may be a high-frequency substrate. The laminated substrate 210 may be formed of a lamination of a plurality of benzocyclobutenes (BCBs). The laminated substrate 210 may be a semiconductor substrate.

Both ends of the input conductive lines 221, 222, 223 and 224 may be provided respectively as a ‘+’ input terminal and a ‘−’ input terminal. The both ends may be connected to a power amplifier (PA) connected to the IPD transformer 200. The IPD transformer 200 of the present embodiment may be connected to a Complementary Metal Oxide Semiconductor (CMOS) power amplifier used in a mobile communication terminal.

In the present embodiment, the four input conductive lines 221, 222, 223 and 224 may be formed in such a way that they are not connected on the laminated substrate 210. To this end, a portion of each of the input conductive lines 221, 222, 223 and 224 may be formed on the top of the laminated substrate 210, the other portion may be formed on the other layer different from the top of the laminated substrate 210, and they may be connected through a via hole.

Each of the input conductive lines 221, 222, 223 and 224 may be implemented to form a loop around the same region of the laminated substrate 210.

A plurality of capacitors 221a, 222a, 223a and 224a may be formed between both ends of the input conductive lines 221, 222, 223 and 224, respectively. The capacitors 221a, 222a, 223a and 224a may be implemented by forming conductive layers with a predetermined area on the different layers of the laminated substrate 210.

The output conductive line 225 may be formed to be adjacent to each of the input conductive lines 221, 222, 223 and 224 so that it generates an electromagnetic coupling with respect to each of the input conductive lines 221, 222, 223 and 224. One end of the output conductive line 225 is provided to an output terminal and the other end thereof may be connected to a ground plane.

In the present embodiment, because each of the input conductive lines 221, 222, 223 and 224 forms a loop around the same region on the laminated substrate 210, the output conductive line 225 may also form a loop around the same region on the laminated substrate 210. Also, the output conductive line 225 may be formed between the input conductive lines 221, 222, 223 and 224 so that it generates an electromagnetic coupling with respect to the input conductive lines 221, 222, 223 and 224.

A portion of the output conductive line 225 maybe formed in one layer of the laminated substrate 210, the other portion of the output conductive line 225 may be formed in the other layer different from the one layer of the laminated substrate 225, and they may be connected through a via hole so that the output conductive line 225 is not directly connected to the input conductive lines 221, 222, 223 and 224.

Each of the power supply pads 241, 242, 243 and 244 may be formed in one region of each of the input conductive lines 221, 222, 223 and 224. A buffer layer (not illustrated) may be formed between the power supply pads 241, 242, 243 and 244 and the input conductive lines 221, 222, 223 and 224. That is, in order to form the power supply pad in one region of each of the input conductive lines 221, 222, 223 and 224, a buffer layer may be formed in one region of each of the input conductive lines 221, 222, 223 and 224 and the power supply pads 241, 242, 243 and 244 may be formed on the buffer layer.

Each of the power supply pads 241, 242, 243 and 244 may be provided as a terminal for supplying power to each of the input conductive lines 221, 222, 223 and 224. The formation location of the power supply pad may be the location in the corresponding input conductive line where an electrical radio-frequency (RF) swing voltage is 0 V. The CMOS power amplifier has no DC ground and thus uses an alternating current (AC) ground, and the ‘RF swing voltage of 0 V’ means the AC ground.

The power supply pads 241, 242, 243 and 244 maybe formed such that a coupling value with respect to the output conductive line 225 adjacent to the input conductive lines 221, 222, 223 and 224 is constant. Because the power supply pads 241, 242, 243 and 244 may be wider in line width than the input conductive lines 221, 222, 223 and 224, an interval from the output conductive line 225 may vary according to their locations. In the present embodiment, the power supply pads 241, 242, 243 and 244 may be respectively formed in the outermost sides 242 and 243 and the innermost sides 241 and 244 of the input conductive lines 221, 222, 223 and 224 forming loops so that the interval between the power supply pads 241, 242, 243 and 244 and the output conductive line 225 is maintained to be equal to the interval between the input conductive lines 221, 222, 223 and 224 and the output conductive line 225.

Also, the power supply pads 241, 242, 243 and 244 may be formed in such a way that the interval between the power supply pads 241, 242, 243 and 244 and the output conductive line 225 and the interval between at least one of the input conductive lines 221, 222, 223 and 224 and the output conductive line 225 are constant. When the power supply pad is formed directly on the input conductive line according to the present embodiment, because a separate conductive line for formation of the power supply pad need not be formed, it is possible to prevent an undesirable coupling that may be generated by other conductive lines.

A harmonic eliminating unit 260 may be formed at both ends of the output conductive line 225.

Because a harmonic component may be contained in an output signal of the IPD transformer 200, the harmonic eliminating unit 260 may be formed to eliminating the harmonic component.

In the present embodiment, the harmonic eliminating unit 260 may be formed in a central region of the loops formed by the input conductive lines 221, 222, 223 and 224 on the laminated substrate 210.

The harmonic eliminating unit 260 may be configured such that inductor and capacitor components are connected in series. The inductor component may be connected to the outside through wire bonding, and the location of the wire bonding may be controlled to tune a harmonic component of a desired band.

A harmonic component of a signal output to an output terminal of the IPD transformer 200 can be removed by the inductor component and the capacitor component.

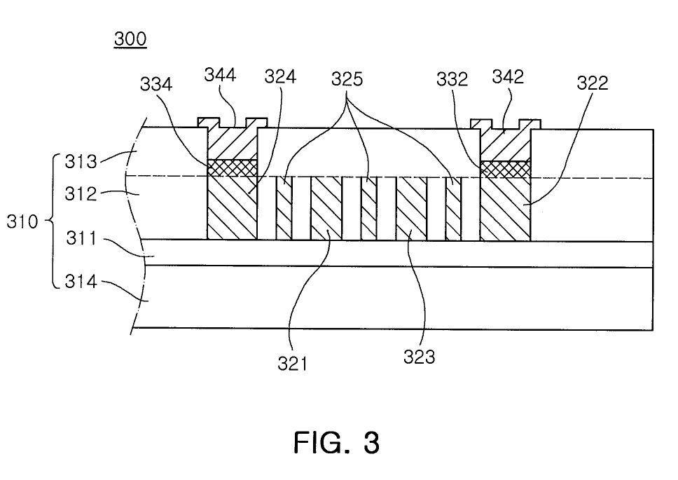

FIG. 3 is a cross-sectional view taken along a line AA′ of FIG. 2.

Referring to FIG. 3, the laminated substrate 310 may include a plurality of dielectric sheets 311, 312 and 313 that are laminated therein. The dielectric sheets 311, 312 and 313 may contain benzocyclobutene (BCB). The benzocyclobutene is a dielectric material with a permittivity of about 2.

The laminated substrate 310 may further include a second dielectric layer 314 that has a different permittivity than the dielectric sheets 311, 312 and 313. The second dielectric layer 314 may be a ceramic laminated body. The laminated substrate 310 may be a semiconductor substrate.

In the present embodiment, the BCB layers 311, 312 and 313 may be formed on the ceramic laminated layer 314 and a plurality of input conductive lines 321, 322, 323 and 324 may be formed in the BCB layers 311, 312 and 313. An output conductive line 325 may be formed between the input conductive lines 321, 322, 323 and 324.

Buffer layers 332 and 334 may be formed on surfaces of the input conductive lines 322 and 324 among the input conductive lines 321, 322, 323 and 324. Te buffer layers 332 and 334 may contain a titanium (Ti)-based metal. The buffer layers 332 and 334 may be formed between the input conductive lines 322 and 324 power supply pads 342 and 344 to serve as a barrier.

The power supply pads 342 and 344 may be provided as a pad for wire bonding with an external power. The power supply pads 342 and 344 may be formed by plating nickel (Ni) and/or aurum (Au) on the buffer layers 332 and 334.

In the present embodiment, the input conductive lines 322 and 324 may be formed in the benzocyclobutene (BCB) laminated substrate 310, and the buffer layers 332 and 334 may be formed on the input conductive lines 322 and 324 in order to form the power supply pads 342 and 344.

The input conductive lines 322 and 324 may be formed of cuprum (Cu). The power supply pads 342 and 344 may be a Ni/Au plating layer. If the power supply pads 342 and 344 are formed directly on the input conductive lines 322 and 324 formed of cuprum (Cu), the cuprum particles of the input conductive lines 322 and 324 may be transferred to the power supply pads 342 and 344. In order to prevent this transfer phenomenon, the buffer layers 332 and 334 may be formed between the input conductive lines 322 and 324 and the power supply pads 342 and 344.

If only a seed layer (not illustrated) is formed on the input conductive lines formed of cuprum (Cu) and then the power supply pads are formed thereon, the benzocyclobutene (BCB) may infiltrate between the input conductive line and the power supply pad because of the characteristics of the BCB layer. Therefore, the input conductive line and the power supply pad may come off from each other, thus leading to a contact failure therebetween.

In the present embodiment, the buffer layers 332 and 334 are formed between the input conductive lines 322 and 324 and the power supply pads 342 and 344, thereby making it possible to prevent the benzocyclobutene (BCB) from infiltrating between the input conductive lines 322 and 324 and the power supply pads 342 and 344.

As described above, the present invention can provide an integrated passive device (IPD) and an IPD transformer, which has a structure capable of minimizing a direct current (DC) resistance when power is applied from the outside.

While the present invention has been shown and described in connection with the exemplary embodiments, it will be apparent to those skilled in the art that modifications and variations can be made without departing from the spirit and scope of the invention as defined by the appended claims.

1. An integrated passive device comprising:
a dielectric laminated substrate which comprises benzocyclobutene (BCB);
a first conductive layer formed in the dielectric laminated substrate;
a buffer layer formed on one region of the first conductive layer in the dielectric laminated substrate; and
a second conductive layer formed on the buffer layer such that a portion of the second conductive layer is exposed to the outside of the dielectric laminated substrate, the interposition of the buffer layer between the first conductive layer and the second conductive layer being configured to prevent the benzocyclobutene from infiltrating between the first conductive layer and the second conductive layer.

2. (canceled)

3. The integrated passive device of claim 1, wherein the first conductive layer is an inductor pattern with a predetermined electrical length.

4. The integrated passive device of claim 1, wherein the buffer layer comprises a titanium (Ti)-based metal.

5. The integrated passive device of claim 1, wherein the second conductive layer comprises gold (Au) and nickel (Ni).

6. The integrated passive device of claim 1, wherein the dielectric laminated substrate comprises:
a first dielectric layer with a first permittivity; and
a second dielectric layer with a second permittivity,
wherein the first conductive layer, the buffer layer, and the second conductive layer are formed on the second dielectric layer.

7. The integrated passive device of claim 6, wherein the second dielectric layer comprises benzocyclobutene (BCB).

8. An integrated passive device (IPD) transformer comprising:
a dielectric laminated substrate, the dielectric laminated substrate comprising benzocyclobutene (BCB);
at least one input conductive line formed on the dielectric laminated substrate, both ends of the input conductive line being provided respectively as input terminals of a ‘+’ signal and a ‘−’ signal;
an output conductive line formed to be adjacent to the input conductive line such that the output conductive line generates an electromagnetic coupling with the input conductive line, one end of the output conductive line being connected to an output terminal, the other end of the output conductive line being connected to a ground terminal;
a buffer layer formed in one region of the input conductive line to prevent infiltration of the benzocyclobutene, from the dielectric laminated substrate, between the input conductive line and the output conductive line; and
a power supply pad formed on the buffer layer such that a portion of the power supply pad is exposed to the outside of the dielectric laminated substrate,
wherein a portion of the input conductive line is formed in one layer of the dielectric laminated substrate and the other portion of the input conductive line is formed in the other layer different from the one layer of the dielectric laminated substrate and is connected through a via hole, and
a portion of the output conductive line is formed in one layer of the dielectric laminated substrate and the other portion of the output conductive line is formed in the other layer different from the one layer of the dielectric laminated substrate and is connected through a via hole, such that the output conductive line is not directly connected to the input conductive line.

9. (canceled)

10. The IPD transformer of claim 8, wherein the buffer layer comprises a titanium (Ti)-based metal.

11. The IPD transformer of claim 8, wherein the power supply pad comprises gold (Au) and nickel (Ni).

12. The IPD transformer of claim 8, wherein the dielectric laminated substrate comprises:
a first dielectric layer with a first permittivity; and
a second dielectric layer with a second permittivity,
wherein the input conductive line, the buffer layer, and the power supply pad are formed on the second dielectric layer.

13. The IPD transformer of claim 12, wherein the second dielectric layer comprises benzocyclobutene (BCB).
